(19) United States
(12) Patent Application Publication
(10) Pub. No.: US 2026/0133502 A1
(43) Pub. Date: May 14, 2026

(54) CLEANING A PORTION OF A LITHOGRAPHY APPARATUS

(71) Applicant: ASML NETHERLANDS B.V., Veldhoven (NL)

(72) Inventors: Ankur Ramesh BAHETI, Wilton, CT (US); Matthew LIPSON, Stamford, CT (US); Brandon Adam EVANS, Norwalk, CT (US)

(73) Assignee: ASML NETHERLANDS B.V., Veldhoven (NL)

(21) Appl. No.: 19/121,474

(22) PCT Filed: Nov. 1, 2023
(86) PCT No.: PCT/EP2023/080493

§ 371 Date: Apr. 16, 2025

Related U.S. Application Data
(60) Provisional application No. 63/423,927, filed on Nov. 9, 2022.

(51) Int. Cl. G03F 7/00; B08B 1/10; B08B 1/30; B08B 3/08; B08B 7/00; C11D 3/04; G01B 11/30; G01N 15/075

(52) U.S. Cl. CPC G03F 7/70925; B08B 1/10; B08B 1/30; B08B 3/08; B08B 7/0035; C11D 3/044; G01B 11/303; G01N 15/075; G03F 7/70508; G03F 7/707; G03F 7/7085

(57) ABSTRACT

Cleaning contamination particles from a clamp of a lithography apparatus is described. Used clamps have burl tops contaminated with contamination particles to be cleaned before returning to service. Currently, to fully clean the burl tops of such a clamp, a hard and electrically conductive coating that covers the burl tops is stripped and a fresh coating is applied. This involves disconnecting a clamp from a chuck, stripping various coatings from non-burl areas of the clamp, and removing high voltage connections. Thereafter, high voltage connections are rebuilt, various coatings are reapplied, and the clamp is then qualified. Finally, the clamp is re-connected to the chuck, and manufacturing may continue. A new cleaning method enables the cleaning of the burl tops without needing to disconnect the clamp or to take the caps off to perform burl top refresh, which can save hours or weeks of downtime.

### CROSS-REFERENCE TO RELATED APPLICATIONS

This application claims priority of US application Ser. No. 63/423,927 which was filed on 9^{th} Nov. 2022, and which is incorporated herein in its entirety by reference.

### TECHNICAL FIELD

The description herein relates generally to methods and systems for cleaning a portion of a lithography apparatus.

### BACKGROUND

A lithography (e.g., projection) apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively.

### SUMMARY

Cleaning contamination particles from a clamp of a lithography apparatus is described. Often the tops of clamp burls are coated with a hard and electrically conductive ceramic such as TiN or CrN. Typically, used clamps have burls or burl tops contaminated with contamination particles which need to be cleaned before returning to service. This contamination may be bound so strongly to the burl top coating that simple mechanical action does not remove it. One way to fully clean a burl top is to strip the hard and electrically conductive coating and apply a fresh such coating. This requires disconnecting the clamp from its chuck, removing various coatings from non-burl areas of the clamp, and removing high voltage connections. Thereafter, high voltage connections are rebuilt and caps are added, various coatings are re-applied, and the clamp is then qualified. Finally, the clamp is re-connected to the chuck, and manufacturing may continue.

Advantageously, new cleaning method(s) and system(s) described below enable the cleaning of the burl tops without needing to disconnect the clamp from its chuck or to remove high voltage connections to perform the burl top refresh, which saves hours of lithography apparatus downtime, and/or has other advantages. Compared to prior approaches, the described methods and systems are better able to eliminate particle contamination from the clamp; require less time for cleaning; does not require disconnecting a chuck or other disassembly of the lithography apparatus; prevents potential damage of the clamps due to mishandling of other cleaning apparatuses; and has other advantages.

According to an embodiment, there is provided a method for cleaning an object support of a lithography apparatus. The method comprises applying a chemical cleaning agent to a surface of the object support to release contamination particles from the surface. The method comprises causing relative movement between a cleaning tool and the surface to clean the contamination particles from the surface. The method comprises applying an organic liquid on the surface to remove the chemical cleaning agent from the surface.

In some embodiments, the method further comprises generating pre-cleaning image data of the surface confirming presence of the contamination particles and/or one or more types of the contamination particles. The image data comprises one or more images from a microscope inspection of the surface.

In some embodiments, the method further comprises determining a pre-cleaning initial flatness of the surface to confirm presence of the contamination particles and a need for cleaning. In some embodiments, the initial flatness is determined using high voltage phase measurement interferometry.

In some embodiments, the method further comprises determining a pre-cleaning contamination particle distribution map for the surface. In some embodiments, the contamination particle distribution map is determined using a microscope inspection. In some embodiments, the contamination particle distribution map is determined using white light interferometry.

In some embodiments, the method further comprises, based on image data of the surface, flatness of the surface, and/or contamination particle distribution on the surface, determining whether and/or where on the surface to apply the chemical cleaning agent, cause the relative movement between the cleaning tool and the surface, and/or apply the organic liquid.

In some embodiments, the method further comprises performing a post-cleaning uniform ion beam figuring on the surface. In some embodiments, the contamination particles are either already completely removed or reduced in size to a small enough size that the uniform ion beam figuring can then remove the contamination particles.

In some embodiments, the method further comprises determining a post-cleaning contamination particle distribution map for the surface, and comparing the post-cleaning contamination particle distribution map to a pre-cleaning contamination particle distribution map for the surface to confirm the method for cleaning successfully removed most or all of the contamination particles from the surface. In some embodiments, the post-cleaning contamination particle distribution map is determined using white light interferometry.

In some embodiments, the method further comprises determining a post-cleaning flatness of the surface, and comparing the post-cleaning flatness to a pre-cleaning initial flatness of the surface to confirm the method for cleaning successfully removed most or all of the contamination particles from the surface. In some embodiments, the post-cleaning flatness is determined using high voltage phase measurement interferometry.

In some embodiments, responsive to the post-cleaning flatness breaching a flatness threshold, the method further comprises performing ion beam figuring on the surface to bring the post-cleaning flatness within a flatness specification.

In some embodiments, the surface comprises a burl top or a portion of a burl top.

In some embodiments, the chemical cleaning agent comprises potassium hydroxide for tantalum contamination particles, a chrome etchant for chrome contamination particles, or a combination thereof.

In some embodiments, the cleaning tool is a glass puck. In some embodiments, the relative movement comprises lateral movement, serpentine movement, circular movement, or a combination thereof.

In some embodiments, the object support is a clamp.

In some embodiments, the cleaning comprises flattening and/or removal of the contamination particles.

In some embodiments, applying the chemical cleaning agent, causing the relative movement, and applying the organic liquid are performed with the clamp coupled to a chuck of the lithography apparatus. In some embodiments, applying the chemical cleaning agent, causing the relative movement, and applying the organic liquid are performed with the clamp disconnected from a chuck of the lithography apparatus. In some embodiments, the object support and the lithography apparatus are associated with semiconductor manufacturing.

According to another embodiment, there is provided a system for cleaning an object support of a lithography apparatus, comprising: a chemical cleaning agent configured to be applied to a surface of the object support to release the contamination particles from the surface; a cleaning tool configured to be caused to move relative to the surface to clean the contamination particles from the surface; and an organic liquid configured to be applied on the surface to remove the chemical cleaning agent from the surface.

According to another embodiment, there is provided a system for cleaning a reticle clamp of a lithography apparatus, comprising: a chemical cleaning agent configured to be applied to a surface of the reticle clamp to release the contamination particles from the surface; a cleaning tool configured to be caused to move relative to the surface to clean the contamination particles from the surface; and an organic liquid configured to be applied on the surface to remove the chemical cleaning agent from the surface.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 schematically depicts a lithography apparatus, according to an embodiment.

FIG. 2 schematically depicts an embodiment of a lithographic cell or cluster, according to an embodiment.

FIG. 3A illustrates a portion of an extreme ultra violet (EUV) lithographic apparatus, according to an embodiment.

FIG. 3B illustrates a portion of a deep ultra violet (DUV) lithographic apparatus, according to an embodiment.

FIG. 3C is an enlarged view of a portion of the lithographic apparatus shown in FIG. 3B, according to an embodiment.

FIG. 4 illustrates examples of contamination particles on a reticle clamp, according to an embodiment.

FIG. 5 illustrates a method for cleaning a clamp of a lithography apparatus, according to an embodiment.

FIG. 6 illustrates a high voltage phase measurement interferometry flatness measurement of a clamp surface, according to an embodiment.

FIG. 7 illustrates a white light interferometry map of contamination particle distribution across burl surfaces, according to an embodiment.

FIG. 8 illustrates a chemical cleaning agent applied to a surface (e.g., one or more burl tops) of a reticle clamp to release contamination particles (too small to be visible in this figure) from the surface, according to an embodiment.

FIG. 9 illustrates a second white light interferometry map, but for a post cleaning contamination particle distribution across the same burl surfaces and clamp shown in FIG. 7, according to an embodiment.

FIG. 10 illustrates white light interferometer inspection data and scanning electron microscope inspection data for a cleaned surface (e.g. a burl top) of the clamp from prior figures, according to an embodiment.

FIG. 11 illustrates another white light interferometry map of contamination particle distribution across burl surfaces after ion beam figuring (and after cleaning), according to an embodiment.

FIG. 12 shows relatively low and high magnification images of a clamp surface—a burl top in this example—at various stages of the cleaning method described in FIG. 5, according to an embodiment.

FIG. 13 is a flow diagram for supplier refurbishment of contaminated clamp surfaces (including the operations of the cleaning method described in FIG. 5), according to an embodiment.

FIG. 14 is a block diagram of an example computer system, according to an embodiment.

### DETAILED DESCRIPTION

In general, a mask or reticle may be a transparent block of material that is covered with a pattern defined by a different, opaque material. Or a mask or reticle may be an opaque block of material coated with a patterned mirror, for example. Various masks are fed into a lithographic apparatus and used to form layers of a semiconductor device. The pattern defined on a given mask or reticle corresponds to features produced in one or more layers of the semiconductor device. Often, a plurality of masks or reticles are automatically fed into a lithographic apparatus during manufacturing and used to form corresponding layers of a semiconductor device. A clamp (e.g., an electrostatic reticle clamp) in the lithographic apparatus is used to secure a masks or reticles during processing. This clamp may become contaminated with particles of material (˜1-3 μm in lateral dimension and >25 nm in height) transferred from reticles causing performance degradation over time, and requiring periodic cleaning to restore performance. These contamination particles may cause performance degradation over time, and, for example, provide nucleation sites for growth of further contamination, and/or cause other process issues.

Cleaning these clamps can require stopping the lithographic apparatus and the manufacturing process. This cleaning can require several hours or weeks to complete, may introduce other contaminants into the system, and/or have other disadvantages. Used clamps often have surfaces such as burl tops contaminated with contamination particles which need to be cleaned before clamps can be returned to service. Often the tops of clamp burls are coated with a hard and electrically conductive ceramic such as TiN or CrN. The contamination may be bound so strongly to the burl top coating that simple mechanical action does not remove it.

To fully clean the burl tops of such a clamp, the hard and electrically conductive coating that covers the burl tops is stripped and a fresh coating is applied. This requires disconnecting a clamp from a chuck, stripping various coatings from non-burl areas of the clamp, stripping the hard and electrically conductive coating, and removing high voltage connections. Thereafter, high voltage connections are rebuilt and caps are added, various coatings including that on the burltops is reapplied, and the clamp is then qualified for resumed manufacturing use. Finally, the clamp is re-connected to the chuck, and manufacturing may continue.

Disconnecting the clamp from the chuck carries inherent risk of clamp and/or chuck damage. Disconnecting also affects clamp flatness such that a complete cycle of burl top flattening operations are required, which adds to the time required for clamp cleaning. The high voltage connections are sealed by attaching additional hardware (for e.g. glass) using structural epoxy. The structural epoxy is strong enough that when removed, barriers underneath are often damaged. Extensive barrier damage around the high voltage connections can render the clamp scrap. With regard to stripping the hard and electrically conductive coating, structures created in the (e.g., glass) surface of the burls to aid in clamping may be mismatched with patterns in the hard and electrically conductive coating. For example, when an original coating is stripped it often leaves behind an imprint of an initial coating pattern. When a fresh coating is applied, there may be registration issues and the fresh coat may already have pre-built non-optimal structures. This can affect the roughness of a clamp and generally requires structure mapping, which further adds to the cleaning cycle time.

In contrast, the present systems and methods provide a new cleaning technique that enables the cleaning of the burl tops and/or other surfaces without needing to disconnect the clamp or remove high voltage connections to perform the burl top refresh. Cleaning the clamps of the lithographic apparatus with the present cleaning methods and systems can also save hours or weeks of downtime associated with prior inspection and cleaning methods, avoid damaging the clamp due to mishandling of a manual cleaning apparatus, and/or have other advantages.

Although specific reference may be made in this text to the manufacture of integrated circuits (ICs), it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively. In addition, any use of the terms “reticle” or “mask” herein may be considered synonymous with the more general term “patterning device.”

As an introduction, prior to transferring a pattern from a patterning device such as a mask to a substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement and/or other inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process.

Lithography is a step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ2/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, overlay measurement, or other methods generally defined as “resolution enhancement techniques” (RET).

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping, or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

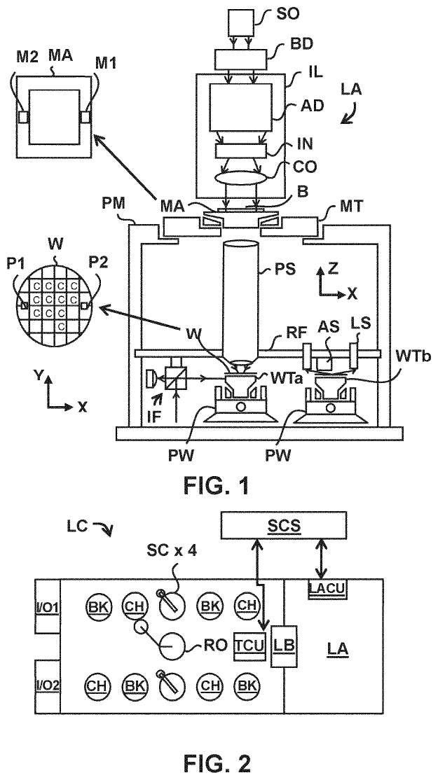

FIG. 1 schematically depicts an embodiment of a lithographic apparatus LA that may be included in and/or associated with the present systems and/or methods. The apparatus comprises: an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame (RF). As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include reticles or masks, programmable mirror arrays, and programmable LCD panels. Reticles or masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic, and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The projection system PS has an optical transfer function which may be non-uniform, which can affect the pattern imaged on the substrate W. For unpolarized radiation such effects can be fairly well described by two scalar maps, which describe the transmission (apodization) and relative phase (aberration) of radiation exiting the projection system PS as a function of position in a pupil plane thereof. These scalar maps, which may be referred to as the transmission map and the relative phase map, may be expressed as a linear combination of a complete set of basis functions. A convenient set is the Zernike polynomials, which form a set of orthogonal polynomials defined on a unit circle. A determination of each scalar map may involve determining the coefficients in such an expansion. Since the Zernike polynomials are orthogonal on the unit circle, the Zernike coefficients may be determined by calculating the inner product of a measured scalar map with each Zernike polynomial in turn and dividing this by the square of the norm of that Zernike polynomial.

The transmission map and the relative phase map are field and system dependent. That is, in general, each projection system PS will have a different Zernike expansion for each field point (i.e. for each spatial location in its image plane). The relative phase of the projection system PS in its pupil plane may be determined by projecting radiation, for example from a point-like source in an object plane of the projection system PS (i.e. the plane of the patterning device MA), through the projection system PS and using a shearing interferometer to measure a wavefront (i.e. a locus of points with the same phase). A shearing interferometer is a common path interferometer and therefore, advantageously, no secondary reference beam is required to measure the wavefront. The shearing interferometer may comprise a diffraction grating, for example a two dimensional grid, in an image plane of the projection system (i.e. the substrate table WTa or WTb) and a detector arranged to detect an interference pattern in a plane that is conjugate to a pupil plane of the projection system PS. The interference pattern is related to the derivative of the phase of the radiation with respect to a coordinate in the pupil plane in the shearing direction. The detector may comprise an array of sensing elements such as, for example, charge coupled devices (CCDs).

The projection system PS of a lithography apparatus may not produce visible fringes and therefore the accuracy of the determination of the wavefront can be enhanced using phase stepping techniques such as, for example, moving the diffraction grating. Stepping may be performed in the plane of the diffraction grating and in a direction perpendicular to the scanning direction of the measurement. The stepping range may be one grating period, and at least three (uniformly distributed) phase steps may be used. Thus, for example, three scanning measurements may be performed in the y-direction, each scanning measurement being performed for a different position in the x-direction. This stepping of the diffraction grating effectively transforms phase variations into intensity variations, allowing phase information to be determined. The grating may be stepped in a direction perpendicular to the diffraction grating (z direction) to calibrate the detector.

The diffraction grating may be sequentially scanned in two perpendicular directions, which may coincide with axes of a co-ordinate system of the projection system PS (x and y) or may be at an angle such as 45 degrees to these axes. Scanning may be performed over an integer number of grating periods, for example one grating period. The scanning averages out phase variation in one direction, allowing phase variation in the other direction to be reconstructed. This allows the wavefront to be determined as a function of both directions.

The transmission (apodization) of the projection system PS in its pupil plane may be determined by projecting radiation, for example from a point-like source in an object plane of the projection system PS (i.e. the plane of the patterning device MA), through the projection system PS and measuring the intensity of radiation in a plane that is conjugate to a pupil plane of the projection system PS, using a detector. The same detector as is used to measure the wavefront to determine aberrations may be used.

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT. Having traversed the patterning device MA, the radiation beam B passes through the projection system PS, which focuses the beam onto a target portion C of the substrate W. With the aid of the second positioner PW and position sensor IF (e.g., an interferometric device, linear encoder, 2-D encoder, or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. 3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above. Combinations and/or variations on the above-described modes of use or entirely different modes of use may also be employed.

A substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, critical dimension (CD), edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns. These patterns can be referred to as “hot spots” or “process window limiting patterns (PWLPs),” which are used interchangeably herein. When controlling a part of a patterning process, it is possible and economical to focus on the hot spots.

When the hot spots are not defective, it is most likely that other patterns are not defective.

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. For example, contamination on reticle clamp membranes (e.g., as described herein) may adversely affect overlay because clamping a reticle over such contamination will distort the reticle. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. As discussed above, a fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating). Another application of diffraction-based metrology is in the measurement of feature width (CD) within a target.

Thus, in a device fabrication process (e.g., a patterning process, a lithography process, etc.), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

Within a metrology system, a metrology apparatus is used to determine one or more properties of the substrate, and in particular, how one or more properties of different substrates vary, or different layers of the same substrate vary from layer to layer. As noted above, the metrology apparatus may be integrated into the lithographic apparatus LA or the lithocell LC or may be a stand-alone device.

To enable the metrology, one or more targets can be provided on the substrate. In an embodiment, the target is specially designed and may comprise a periodic structure. In an embodiment, the target is a part of a device pattern, e.g., a periodic structure of the device pattern. In an embodiment, the device pattern is a periodic structure of a memory device (e.g., a Bipolar Transistor (BPT), a Bit Line Contact (BLC), etc. structure).

In an embodiment, the target on a substrate may comprise one or more 1-D periodic structures (e.g., gratings), which are printed such that after development, the periodic structural features are formed of solid resist lines. In an embodiment, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

In an embodiment, one of the parameters of interest of a patterning process is overlay. Overlay can be measured using dark field scatterometry in which the zeroth order of diffraction (corresponding to a specular reflection) is blocked, and only higher orders processed. Diffraction-based overlay using dark-field detection of the diffraction orders enables overlay measurements on smaller targets. These targets can be smaller than the illumination spot and may be surrounded by device product structures on a substrate. In an embodiment, multiple targets can be measured in one radiation capture.

As lithography nodes keep shrinking, more and more complicated wafer designs may be implemented. Various tools and/or techniques may be used by designers to ensure complex designs are accurately transferred to physical wafers. These tools and techniques may include mask optimization, source mask optimization (SMO), OPC, design for control, and/or other tools and/or techniques. For example, a source mask optimization process is described in U.S. Pat. No. 9,588,438 titled “Optimization Flows of Source, Mask and Projection Optics”, which is incorporated in its entirety by reference.

The present systems, and/or methods may be used as stand-alone tools and/or techniques, and/or or used in conjunction with semiconductor manufacturing processes, to enhance the accurate transfer of complex designs to physical wafers.

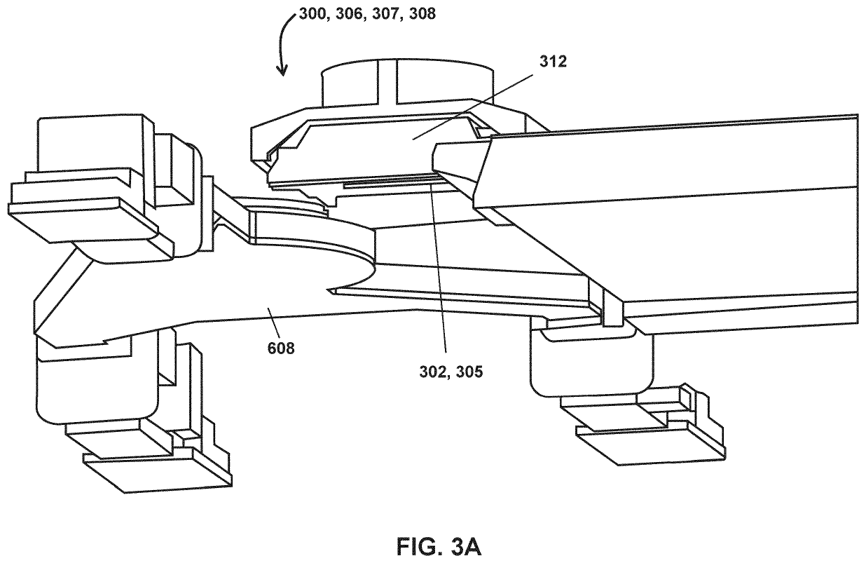

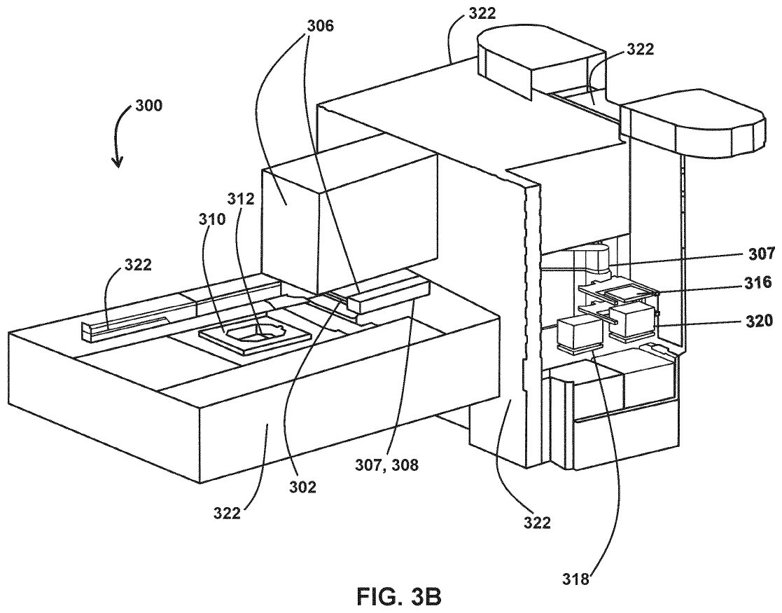

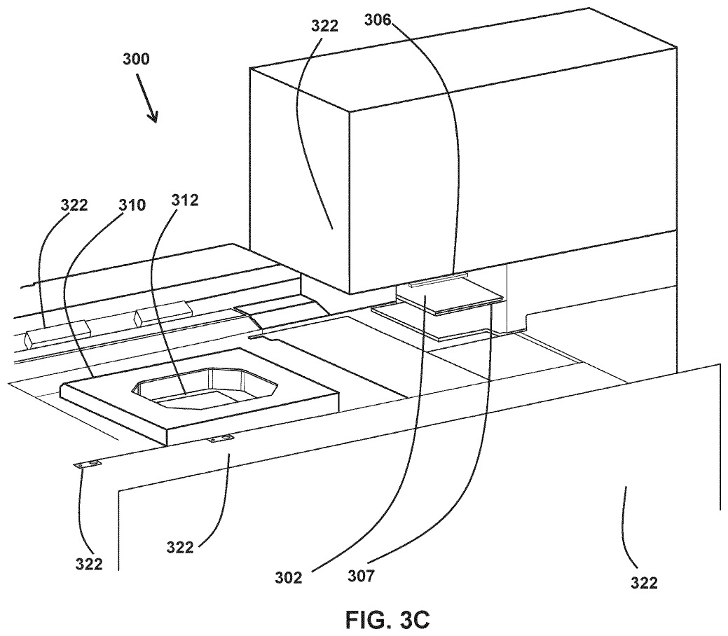

As described above, the present cleaning system is configured to be used to clean a clamp of a lithographic apparatus. By way of a non-limiting example, FIG. 3A, FIG. 3B, and FIG. 3C illustrate example portions of lithographic apparatuses 300 (e.g., similar to an or the same as the lithographic apparatus shown in FIG. 1). FIG. 3A illustrates a portion of an extreme ultra violet (EUV) lithographic apparatus. FIG. 3B illustrates a portion of a deep ultra violet (DUV) lithographic apparatus. FIG. 3C is an enlarged view of a portion of the lithographic apparatus shown in FIG. 3B, according to an embodiment.

FIG. 3A illustrates example lithographic apparatus components in proximity to a clamp 312 of lithographic apparatus 300 including a tool handler 306, 307, 308, and/or other components. Lithographic apparatus 300 may include an EUV inner pod (EIP) 305, a rapid exchange device (RED), and/or other components. In some embodiments, lithographic apparatus 300 can be configured for deep ultraviolet (DUV) lithography with one or more adjustments from what is shown in FIG. 3A. FIG. 3B illustrates an example DUV apparatus (e.g., with a clamp 312 of lithographic apparatus 300 in these figures) and various components of lithographic apparatus 300 including a tool handler 306, 307, 308, reticle chuck 310, reticle clamp(s) 312, and/or other components.

In some embodiments, tool handler 306, 307, 308 comprises a reticle handler turret gripper 306, a reticle handler robot gripper 307 (having associated components 308, etc. for gripping a reticle during transport), and/or other components. Reticle handler robot gripper 307 may, for example, move a reticle from a pod 320 (e.g., after a user places a reticle in pod 320). Reticle handler turret gripper 306 may, for example, move a reticle from reticle handler robot gripper 307 to reticle clamp(s) 312. Lithographic apparatus 300 may include various other mechanical components 322 (translation mechanisms, elevation mechanisms, rotational mechanisms, motors, power generation and transmission components, structural components, etc.) configured to facilitate movement and control of reticle 302 through lithographic apparatus 300. For example, lithographic apparatus 300 may include an EUV inner pod (EIP), and a rapid exchange device (RED), and/or other components.

The present systems and methods are configured to be used to clean clamp(s) 312 (e.g., reticle clamp(s)) of lithographic apparatus 300. In other embodiments, the present systems and methods described herein can be configured to clean any object support of a lithographic apparatus. An object support can include any clamp (e.g., vacuum or electrostatic clamp), or support structure in a lithographic apparatus including but not limited to reticle (also referred to as mask) clamps, wafer (also referred to as substrate) clamps, and wafer tables. FIG. 3C is an enlarged view of a portion of apparatus 300. FIG. 3C shows a reticle 302, reticle handler turret gripper 306, reticle chuck 310, reticle clamp(s) 312, mechanical components 322, reticle handler robot gripper 307, and/or other components. As shown in FIG. 3C, reticle handler turret gripper 306 is configured to move reticle 302 from reticle handler robot gripper 307 to reticle clamp(s) 312. Moving reticle 302 may comprise moving reticle 302 toward or away from the clamp(s) 312 in horizontal, vertical, and/or other directions. Reticle handler turret gripper 306 and/or reticle handler robot gripper 307 may include various motors, translators, rotational components, clamps, clips, power sources, power transmission components, vacuum mechanisms, and/or other components that facilitate the movement of reticle 302.

Contamination particles on clamp contact surfaces, such as burls, often aggregate and grow bigger over time on a clamp surface, hence the need for regular cleaning. Contamination particles typically range between about 2-5 μm in a lateral dimension, and up to about 100-200 nm in height (or thickness from the surface of a burl of the clamp). As the number of particles increases and the sizes of the contamination particles grow, performance degradation such as overlay drift and/or other problems may occur. The overlay can drift by as much as about 1 nm within a relatively short period of time (e.g., 1-3 months), for example, and thus requires frequent cleaning, as this drift is intolerable for semiconductor production. Apparatuses, systems, and methods for cleaning relevant portions (e.g., clamp reticle and/or wafer contact areas) of a lithographic apparatus are therefore desirable.

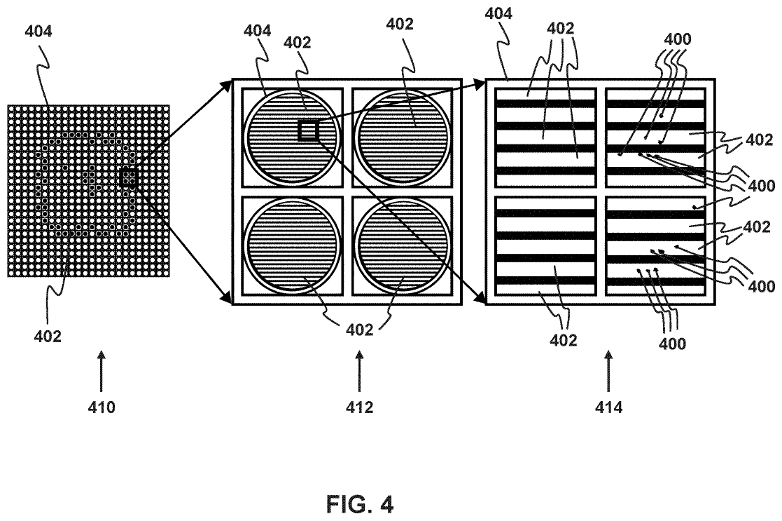

FIG. 4 illustrates examples of contamination particles 400 on reticle contact areas 402 (e.g., a clamp surface) of a reticle clamp 404. In this example, reticle contact areas 402 (clamp surfaces) are burl surfaces. Burl surfaces may undulate and/or have other shapes so that only certain portions of a burl touch a reticle. View 410 of FIG. 4 illustrates white light interferometer data showing contaminated burls (in a circular distribution) on a clamp. The contamination may appear at burl surface peaks, for example, for an embodiment with an undulating surface. View 412 illustrates a relatively low magnification (e.g., 20×) image of four different burls. View 414 illustrates higher magnification (e.g., 100×) images showing clean burls on the left side and contaminated burls on the right side of view 414. Note that each burl has ridge surfaces, or tops, that form reticle contact areas 402.

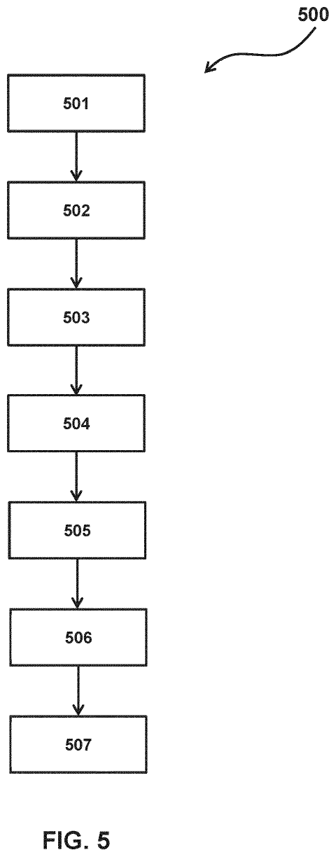

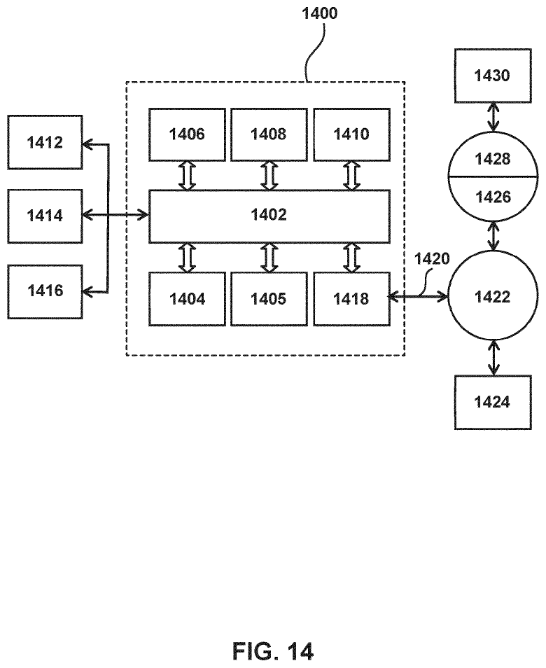

FIG. 5 illustrates a method 500 for cleaning a clamp of a lithography apparatus. The may be a clamp (e.g., an electrostatic clamp, as described above), and/or other clamps/object support surfaces. Cleaning may include flattening and/or removal of contamination particles from the clamp, and/or other operations. In some embodiments, one or more operations of method 500 may be controlled by one or more processors and/or a computing system, as described below (see FIG. 14). The operations of method 500 (e.g., applying a chemical cleaning agent, causing relative movement, applying an organic liquid, and other operations described below) may be performed with the clamp coupled to, or disconnected from, a chuck of a lithography apparatus. The operations of method 500 presented below are intended to be illustrative. In some embodiments, method 500 may be accomplished with one or more additional operations not described, and/or without one or more of the operations discussed. Additionally, the order in which the operations of method 500 are illustrated in FIG. 5 and described below is not intended to be limiting.

In some embodiments, one or more operations of method 500 may be implemented in and/or controlled by one or more processing devices (e.g., a digital processor, an analog processor, a digital circuit designed to process information, an analog circuit designed to process information, a state machine, and/or other mechanisms for electronically processing information, as described with respect to FIG. 14 below). The one or more processing devices may include one or more devices executing some or all of the operations of method 500 in response to instructions stored electronically on an electronic storage medium. The one or more processing devices may include one or more devices configured through hardware, firmware, and/or software to be specifically designed for execution of one or more of the operations of method 500 (e.g., see discussion related to FIG. 14 below). For example, the one or more processing devices may run software configured to form a mosaic of images of one or more clamp surfaces, control performance of an initial flatness measurement, facilitate determination of an initial particle distribution map, controlling a uniform hit using ion beam figuring, facilitating determination of a final particle distribution map and/or comparing the final particle distribution map to the initial particle distribution map, controlling performance of a final flatness measurement, and/or perform other operations.

At an operation 501, pre-cleaning image data of a surface of the clamp confirming presence of the contamination particles, confirming one or more types of the contamination particles, and/or confirming other information is generated. In some embodiments, the types of particles include tantalum contamination particles, chrome contamination particles, and/or other types of contamination particles. In some embodiments, the surface comprises a burl top or a portion of a burl top. In some embodiments, the image data comprises one or more images from a microscope inspection of the surface. Two or more of these images may be (electronically) coupled or stitched together to form a mosaic of images showing burl top surfaces (or portions thereof). Microscope magnifications of 10-100× may be employed in this inspection, for example. The mosaic of images may be analyzed to confirm presence of contamination particles, types of contamination particles, and/or other information.

At an operation 502, a pre-cleaning initial flatness of the surface is determined. The pre-cleaning flatness is determined to confirm presence of the contamination particles and a need for cleaning, for example. In some embodiments, a computer system (such as the computer system shown in FIG. 14 and described below) is configured to determine a pre-cleaning initial flatness of the surface to confirm presence of the contamination particles and a need for cleaning. In some embodiments, the initial flatness is determined using high voltage phase measurement interferometry and/or other methods. In some embodiments, the computer system forms a portion of a high voltage phase measurement interferometer.

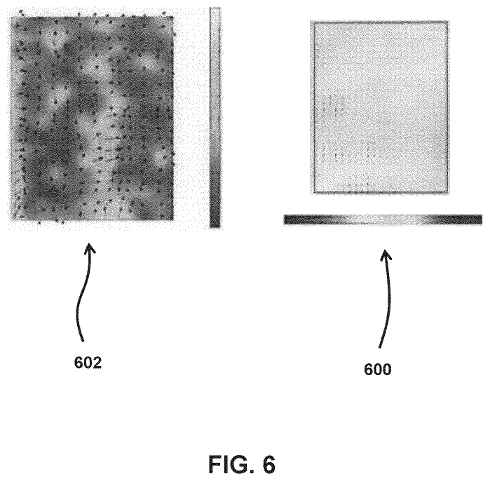

By way of a non-limiting example, FIG. 6 illustrates high voltage phase measurement interferometry flatness measurement data 600 for a clamp surface. FIG. 6 also illustrates corresponding flatness measurement data 602 for the clamp surface obtained before the clamp was removed from service. The arrows show how the unflatness caused by the contamination distorts the surface of a clamped reticle such that the image projected from the reticle to the wafer is incorrectly aligned. As can be seen by the variable shading colors across each data set, the flatness of this clamp surface varies inconsistently across the clamp surface.

Returning to FIG. 5, at an operation 503, a pre-cleaning contamination particle distribution map for the surface is determined. In some embodiments, the pre-cleaning contamination particle distribution map is determined using a microscope inspection. In some embodiments, the contamination particle distribution map is determined using white light interferometry.

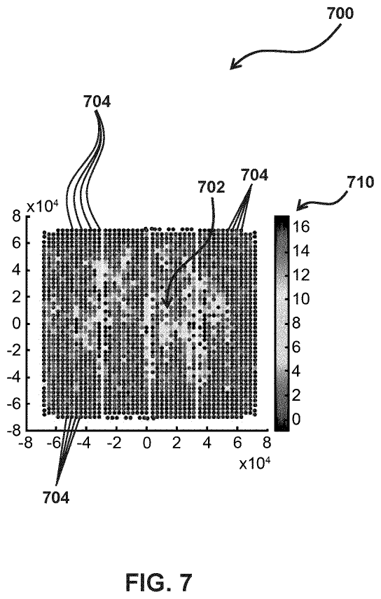

By way of a non-limiting example, FIG. 7 illustrates a white light interferometry map 700 of contamination particle 702 distribution across burl surfaces 704. Each dot in FIG. 7 is a burl surface 704 on the clamp, and the shading scale 710 maps out the number of particles per burl surface (the particle distribution matches the overlay signature for the clamp in this example).

Returning to FIG. 5, at operation 504, a chemical cleaning agent is applied to a surface (e.g., one or more burl tops) of the reticle clamp to release contamination particles from the surface. In some embodiments, the chemical cleaning agent comprises potassium hydroxide for tantalum contamination particles, a chrome etchant for chrome contamination particles, or a combination thereof. Chemistries required for removal of other particles, as may be identified by such techniques as Scanning Electron Microscopy/Energy Dispersive Spectroscopy, will be known to those skilled in the art. The potassium hydroxide may be a 50% potassium hydroxide solution, for example, and/or other solutions.

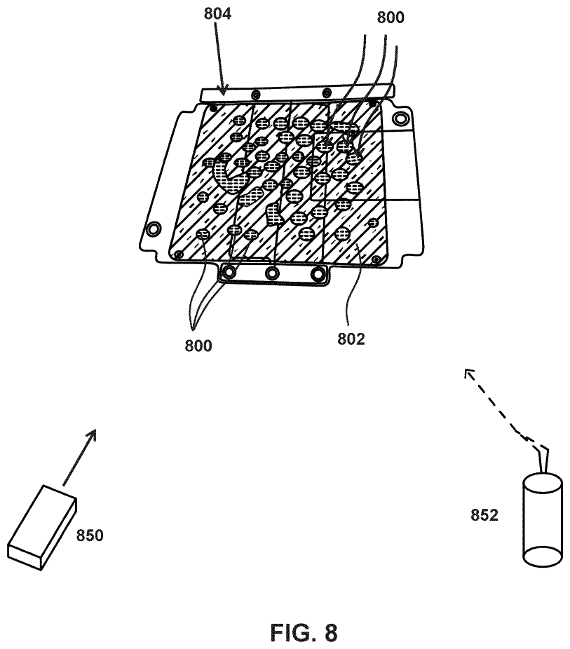

By way of a non-limiting example, FIG. 8 illustrates a chemical cleaning agent 800 applied to a surface 802 (e.g., one or more burl tops) of a reticle clamp 804 to release contamination particles (too small to be visible in this figure) from surface 802. In this example, the chemical cleaning agent is a potassium hydroxide solution. The potassium hydroxide solution is selected for cleaning because the contamination particles are tantalum contamination particles in this example (e.g. determined based on operations 501, 502, and/or 503 as described above). Chemical cleaning agent 800 may be used in combination with a cleaning tool 850 as (e.g., a mechanical cleaning tool such as a glass puck) to clean contamination particles from surface 802, and/or an organic liquid 852 applied on surface 802 (e.g., to rinse surface 802) and remove chemical cleaning agent 800 from surface 802, as described below.

Returning to FIG. 5, in some embodiments, operation 504 includes causing relative movement between a cleaning tool and the surface to clean the contamination particles from the surface. In some embodiments, the cleaning tool can be configured to move relative to the surface, the surface can be configured to move relative to the cleaning tool, or the cleaning tool and the surface can be configured to move relative to each other. In some embodiments, the cleaning tool is a glass puck or other similar cleaning tool. The cleaning tool may be any cleaning tool that is sufficiently flat and chemically inactive toward the cleaning chemicals. The relative movement may comprise lateral movement, serpentine movement, circular movement, or a combination thereof. In some embodiments, the relative movement may be caused by a human operator, a mechanical actuator (e.g., controlled by a computer system such as the computer system shown and described in FIG. 14 below), and/or other devices. The relative movement is configured to clean the contamination particles from the clamp. For example, the relative movement may range from at least about a few tenths of a micrometer (μm) to at least about 4 millimeters (mm). As another example, the relative movement may range from at least about a few tenths of a micrometer (μm) to at least about 4 millimeters (mm) in a non-scan direction of the lithography apparatus, and to at least about 2 mm in a scan direction of the lithography apparatus. (However, these movements may be significantly larger if necessary, for example, if a human operator is causing the relative movement).

In some embodiments, operation 504 comprises receiving entry and/or selection of control commands from a user via a user interface. The control commands comprise instructions for moving the cleaning tool based on a region on interest of the chuck of the lithography apparatus (e.g., surfaces such as burl tops), and/or other control commands.

In some embodiments, operation 504 includes determining whether and/or where on the surface to apply the chemical cleaning agent, cause the relative movement between the cleaning tool and the surface, apply the organic liquid (operation 505 described below), and/or perform other operations. One or more of these determinations may be made based on image data of the surface (see operation 501), flatness of the surface (see operation 502), a contamination particle distribution on the surface (see operation 503), and/or other information, for example. A computer system (such as the computer system shown in FIG. 14 and described below) may be configured for determining whether and/or where on the surface to apply the chemical cleaning agent, where to cause the relative movement between the cleaning tool and the surface, and/or where to apply the organic liquid, based on image data of the surface, flatness of the surface, the contamination particle distribution on the surface, and/or other information.

At operation 505, an organic liquid is applied on the surface. The organic liquid is applied to the surface and remove the chemical cleaning agent from the surface. In some embodiments, the organic liquid is an alcohol such as isopropyl alcohol, and/or other organic liquids. The organic liquid may be dried (e.g., with a drying tool such as a lint free wipe, a towel, a blower, etc.). In some embodiments, an organic liquid such as isopropyl alcohol may be configured to evaporate or otherwise dry relatively quickly to enhance operation 505.

At an operation 506, a post-cleaning uniform ion beam figuring is performed on the surface. In some embodiments, the contamination particles are either already completely removed from the surface, or are reduced in size to a small enough size that the uniform ion beam figuring can then remove the contamination particles.

In some embodiments, at operation 506, a post-cleaning contamination particle distribution map for the surface is determined. The post-cleaning contamination particle distribution map may be compared to a pre-cleaning contamination particle distribution map for the surface to confirm method 500 for cleaning the surface successfully removed most or all of the contamination particles from the surface. In some embodiments, the post-cleaning contamination particle distribution map is determined using white light interferometry and/or other inspection techniques. In some embodiments, a computer system (such as the computer system shown in FIG. 14 and described below) may be configured for determining a post-cleaning contamination particle distribution map for the surface, and comparing the post-cleaning contamination particle distribution map to a pre-cleaning contamination particle distribution map for the surface to confirm the method for cleaning successfully removed most or all of the contamination particles from the surface.

At an operation 507, a post-cleaning flatness of the surface is determined, and the post-cleaning flatness is compared to the pre-cleaning initial flatness of the surface to confirm the method for cleaning successfully removed most or all of the contamination particles from the surface. The post-cleaning flatness may be determined using high voltage phase measurement interferometry, for example. Responsive to the post-cleaning flatness breaching a flatness threshold (e.g., not yet being flat enough), method 500 and/or operation 507 further comprises performing additional ion beam figuring on the surface to bring the post-cleaning flatness to within a flatness specification. In some embodiments, a computer system (such as the computer system shown in FIG. 14 and described below) may be configured for determining a post-cleaning flatness of the surface, and comparing the post-cleaning flatness to a pre-cleaning initial flatness of the surface to confirm the method for cleaning successfully removed most or all of the contamination particles from the surface.

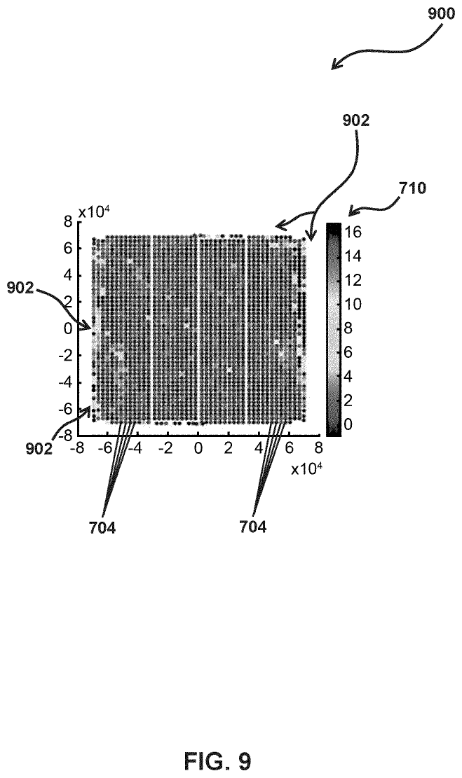

By way of several more non-limiting examples, FIGS. 9-13 illustrate various examples of the features described above. FIG. 9 illustrates a second white light interferometry map 900, but for a post cleaning contamination particle 902 distribution across the same burl surfaces 704 and clamp shown in FIG. 7. Each dot in FIG. 9 is again a burl surface 704 on the clamp, and the shading scale 710 maps out the number of particles per burl surface. As shown in FIG. 9, after cleaning with potassium hydroxide (see FIG. 8), contamination particle 902 distribution is changed relative to contamination particle 702 distribution. As can be observed, the particles from the center of the clamp were removed or moved away from the center of the clamp toward the edges.

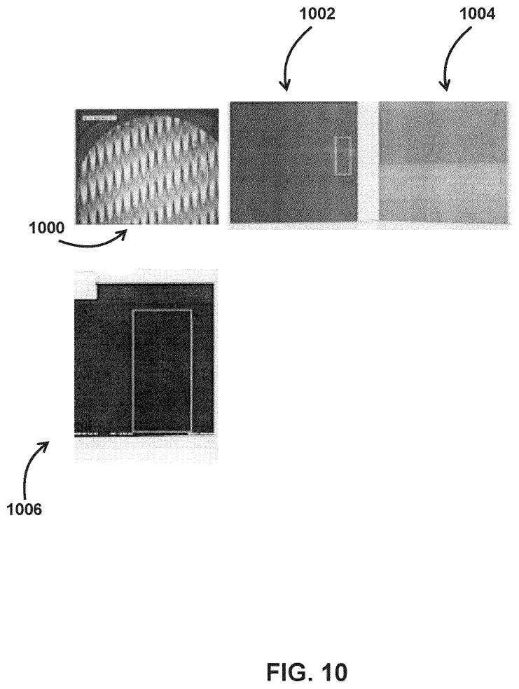

FIG. 10 illustrates white light interferometer inspection data 1000, and scanning electron microscope inspection data 1002, 1004, and 1006 for a cleaned surface (e.g. a burl top) of the clamp from prior figures. In some embodiments, other data such as energy-dispersive X-ray spectroscopy data for a cleaned surface may be used. All of this data indicates that the contamination particles (e.g., tantalum oxide in this example) on the clamp surface have been removed by the cleaning. For example, no contamination particles are visible in white light interferometer inspection data 1000 (e.g., an image of a burl top). The similar and/or low contrasts in the backscattered electron measurements in scanning electron microscope data 1002, 1004, and 1006 indicates a homogeneous burl top surface composition (free of tantalum oxide contamination particles). Similarly, energy-dispersive X-ray spectroscopy data may be obtained to determine whether a homogeneous burl top surface composition exists.

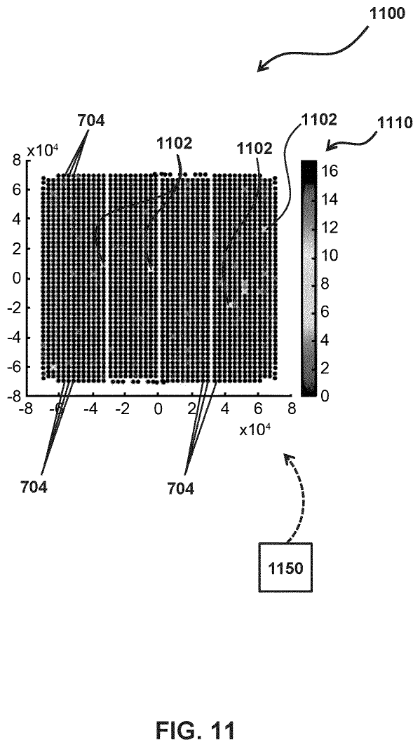

FIG. 11 illustrates another white light interferometry map 1100 of contamination particle distribution across burl surfaces after ion beam figuring (and after cleaning), according to an embodiment. Map 1100 shows a post cleaning and ion beam figuring contamination particle 1102 distribution across the same burl surfaces 704 and clamp shown in FIG. 7 and FIG. 9. The ion beam figuring may be performed by an ion beam figuring system 1150, for example. Each dot in FIG. 11 is again a burl surface 704 on the clamp, and the shading scale 1110 maps out the number of particles per burl surface. As shown in FIG. 11, after cleaning with potassium hydroxide (see FIG. 8) and ion beam figuring, contamination particle 1102 distribution is changed relative to contamination particle 702 and/or 902 distribution. As can be observed, the clamp is relatively clean of any particles 1102.

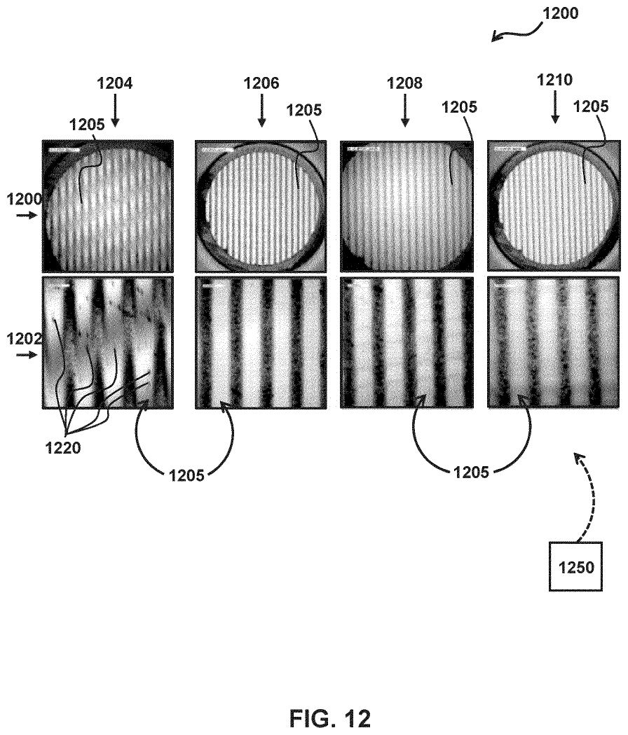

FIG. 12 shows relatively low 1200 and high 1202 magnification images of a clamp surface a burl top in this example—at various stages of the cleaning method shown in FIG. 5 (e.g., method 500 shown in FIG. 5). These images may be obtained with a pre and/or post cleaning imager 1250 such as a microscope, a white light interferometer, and/or other imagers (e.g., where imager 1250 is both the pre and post cleaning imager 1250). FIG. 12 illustrates white light interferometer images of an as received 1204 clamp surface 1205, a post potassium hydroxide and cleaning tool cleaned 1206 surface 1205 (e.g. post operation 504 shown in FIG. 5 and described above), a post organic liquid cleaned 1208 surface 1205 (e.g. post operation 505 shown in FIG. 5), and a post ion beam figuring cleaned 1210 surface 1205. FIG. 12 illustrates how contamination particles 1220 present on as received 1204 clamp surface 1205 are removed by these cleaning operations. For example, particles 1220 are not present after potassium hydroxide and cleaning tool cleaning 1206.

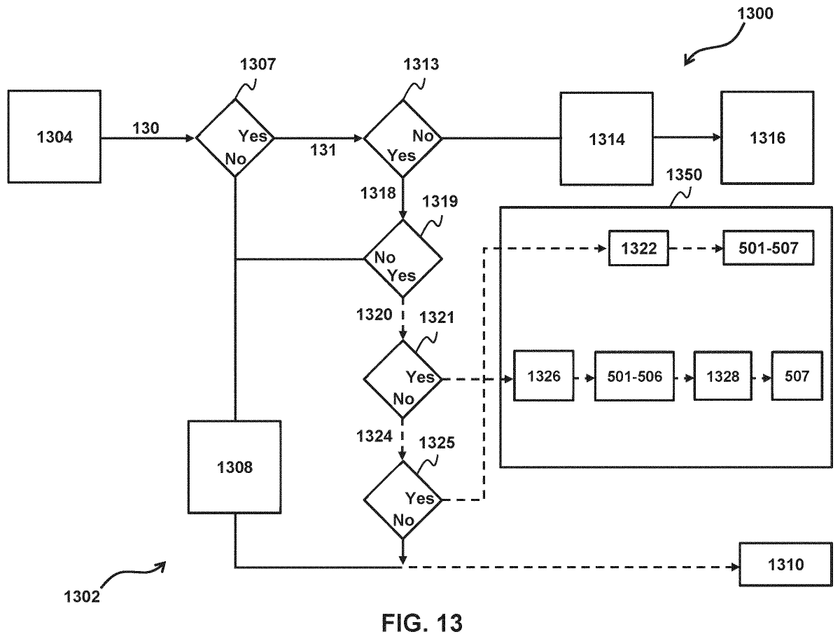

FIG. 13 is a flow 1300 diagram 1302 for supplier refurbishment of contaminated clamp surfaces (including the operations of cleaning method 500 described above). Note that flow 1300 may also or instead be performed by a clamp owner and/or some other provider. Flow 1300 begins with a clamp being returned 1304 to the supplier. A typical clamp may be returned 1304 after about 1000 reticle loads (e.g., as described related to FIGS. 3A, 3B, and 3C above), for example. A determination 1306 as to whether a contaminated and/or damaged (e.g., burl damage) clamp surface is repairable is made. If not repairable (“no” at decision block 1307), the clamp is disconnected from the chuck 1308, and the clamp is stripped and re-coated 1310, which can take up to 15 weeks to complete. If repairable (“yes” at decision block 1307), a determination 1312 is made as to whether the clamp has been contaminated (e.g., with particles as described above). If not contaminated (“no” at decision block 1313), the clamp remains contacted to the chuck 1314, and a low usage repair, cleaning, and/or other operations may be performed 1316 on the clamp and/or clamp surface.

If the clamp has been contaminated (“yes” at decision block 1313), a determination 1318 is made as to whether a sufficient amount (e.g., greater than about a 150 nm thickness) of burl top coating is present on the clamp surface. If so, (“yes” at decision block 1319), a determination 1320 is made as to whether a repair and/or cleaning 1350 can be performed without disconnecting the clamp from the chuck. If it can (“yes” at decision block 1321), the clamp remains contacted to the chuck 1322, the operations of method 500 described above (e.g., at least the chemical cleaning agent and cleaning tool operation 504, and/or the ion beam figuring operation 506) are performed on the clamp surface. If the repair and/or cleaning 1350 cannot be performed with the clamp contacted to the chuck (“no” at decision block 1321), a determination 1324 is made as to whether the repair and/or cleaning 1350 can be performed if the clamp is disconnected from the chuck. If so (“yes” at decision block 1325), the clamp is disconnected 1326 from the chuck, the operations of method 500 described above (e.g., at least the chemical cleaning agent and cleaning tool operation 504) are performed on the clamp surface, the clamp is re-contacted to the chuck 1328, and ion beam figuring operation 507 is performed on the clamp surface.

FIG. 14 is a block diagram that illustrates a computer system 1400 that can assist in implementing the methods, flows, or the system(s) disclosed herein. Computer system 1400 may be included in and/or electronically coupled to lithography apparatus LA described above (FIG. 1, FIG. 3A, etc.). Computer system 1400 includes a bus 1402 or other communication mechanism for communicating information, and a processor 1404 (or multiple processors 1404, 1405, etc.) coupled with bus 1402 for processing information. Computer system 1400 also includes a main memory 1406, such as a random access memory (RAM) or other dynamic storage device, coupled to bus 1402 for storing information and instructions to be executed by processor 1404. Main memory 1406 also may be used for storing temporary variables or other intermediate information during execution of instructions to be executed by processor 1404. Computer system 1400 further includes a read only memory (ROM) 1408 or other static storage device coupled to bus 1402 for storing static information and instructions for processor 1404. A storage device 1410, such as a magnetic disk or optical disk, is provided and coupled to bus 1402 for storing information and instructions.

Computer system 1400 may be coupled via bus 1402 to a display 1412, such as a cathode ray tube (CRT) or flat panel or touch panel display for displaying information to a computer user. An input device 1414, including alphanumeric and other keys, is coupled to bus 1402 for communicating information and command selections to processor 1404. Another type of user input device is cursor control 1416, such as a mouse, a trackball, or cursor direction keys for communicating direction information and command selections to processor 1404 and for controlling cursor movement on display 1412. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more flows and/or methods described herein may be performed by computer system 1400 in response to processor 1404 executing one or more sequences of one or more instructions contained in main memory 1406. Such instructions may be read into main memory 1406 from another computer-readable medium, such as storage device 1410. Execution of the sequences of instructions contained in main memory 1406 causes processor 1404 to perform the flows and/or process steps described herein. One or more processors in a multi-processing arrangement may also be employed to execute the sequences of instructions contained in main memory 1406. In an alternative embodiment, hard-wired circuitry may be used in place of or in combination with software instructions. Thus, the description herein is not limited to any specific combination of hardware circuitry and software.

The term “computer-readable medium” or “machine readable medium” as used herein refers to any medium that participates in providing instructions to processor 1404 for execution. Such a medium may take many forms, including but not limited to, non-volatile media, volatile media, and transmission media. Non-volatile media include, for example, optical or magnetic disks, such as storage device 1410. Volatile media include dynamic memory, such as main memory 1406.

Transmission media include coaxial cables, copper wire and fiber optics, including the wires that comprise bus 1402. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 1404 for execution. For example, the instructions may initially be borne on a magnetic disk of a remote computer. The remote computer can load the instructions into its dynamic memory and send the instructions over a network such as the internet. A modem local to computer system 1400 can receive the data and use an infrared transmitter to convert the data to an infrared signal. An infrared detector coupled to bus 1402 can receive the data carried in the infrared signal and place the data on bus 1402. Bus 1402 carries the data to main memory 1406, from which processor 1404 retrieves and executes the instructions. The instructions received by main memory 1406 may optionally be stored on storage device 1410 either before or after execution by processor 1404.

Computer system 1400 may also include a communication interface 1418 coupled to bus 1402. Communication interface 1418 provides a two-way data communication coupling to a network link 1420 that is connected to a local network 1422. For example, communication interface 1418 may be an integrated services digital network (ISDN) card or a modem to provide a data communication connection to a corresponding type of telephone line. As another example, communication interface 1418 may be a local area network (LAN) card to provide a data communication connection to a compatible LAN. Wireless links may also be implemented. In any such implementation, communication interface 1418 sends and receives electrical, electromagnetic, or optical signals that carry digital data streams representing various types of information.

Network link 1420 typically provides data communication through one or more networks to other data devices. For example, network link 1420 may provide a connection through local network 1422 to a host computer 1424 or to data equipment operated by an Internet Service Provider (ISP) 1426. ISP 1426 in turn provides data communication services through the worldwide packet data communication network, now commonly referred to as the “Internet” 1428. Local network 1422 and Internet 1428 both use electrical, electromagnetic, or optical signals that carry digital data streams.

The signals through the various networks and the signals on network link 1420 and through communication interface 1418, which carry the digital data to and from computer system 1400, are exemplary forms of carrier waves transporting the information.

Computer system 1400 can send messages and receive data, including program code, through the network(s), network link 1420, and communication interface 1418. In the Internet example, a server 1430 might transmit a requested code for an application program through Internet 1428, ISP 1426, local network 1422 and communication interface 1418. One such downloaded application may provide all or part of a method described herein, for example. The received code may be executed by processor 1404 as it is received, and/or stored in storage device 1410, or other non-volatile storage for later execution. In this manner, computer system 1400 may obtain application code in the form of a carrier wave.

Various embodiments of the present systems and methods are disclosed in the subsequent list of numbered clauses:
1. A method for cleaning an object support of a lithography apparatus, comprising: applying a chemical cleaning agent to a surface of the object support to release contamination particles from the surface; causing relative movement between a cleaning tool and the surface to clean the contamination particles from the surface; and applying an organic liquid on the surface to remove the chemical cleaning agent from the surface.
2. The method of any of the previous clauses, further comprising generating pre-cleaning image data of the surface confirming presence of the contamination particles and/or one or more types of the contamination particles.
3. The method of any of the previous clauses, wherein the image data comprises one or more images from a microscope inspection of the surface.
4. The method of any of the previous clauses, further comprising determining a pre-cleaning initial flatness of the surface to confirm presence of the contamination particles and a need for cleaning.
5. The method of any of the previous clauses, wherein the initial flatness is determined using high voltage phase measurement interferometry.
6. The method of any of the previous clauses, further comprising determining a pre-cleaning contamination particle distribution map for the surface.
7. The method of any of the previous clauses, wherein the contamination particle distribution map is determined using a microscope inspection.
8. The method of any of the previous clauses, wherein the contamination particle distribution map is determined using white light interferometry.
9. The method of any of the previous clauses, further comprising, based on image data of the surface, flatness of the surface, and/or contamination particle distribution on the surface, determining whether and/or where on the surface to apply the chemical cleaning agent, cause the relative movement between the cleaning tool and the surface, and/or apply the organic liquid,.
10. The method of any of the previous clauses, further comprising performing a post-cleaning uniform ion beam figuring on the surface.
11. The method of any of the previous clauses, wherein the contamination particles are either already completely removed or reduced in size to a small enough size that the uniform ion beam figuring can then remove the contamination particles.
12. The method of any of the previous clauses, further comprising determining a post-cleaning contamination particle distribution map for the surface, and comparing the post-cleaning contamination particle distribution map to a pre-cleaning contamination particle distribution map for the surface to confirm the method for cleaning successfully removed most or all of the contamination particles from the surface.
13. The method of any of the previous clauses, wherein the post-cleaning contamination particle distribution map is determined using white light interferometry.
14. The method of any of the previous clauses, further comprising determining a post-cleaning flatness of the surface, and comparing the post-cleaning flatness to a pre-cleaning initial flatness of the surface to confirm the method for cleaning successfully removed most or all of the contamination particles from the surface.
15. The method of any of the previous clauses, wherein the post-cleaning flatness is determined using high voltage phase measurement interferometry.
16. The method of any of the previous clauses, wherein, responsive to the post-cleaning flatness breaching a flatness threshold, the method further comprises performing ion beam figuring on the surface to bring the post-cleaning flatness within a flatness specification.
17. The method of any of the previous clauses, wherein the surface comprises a burl top or a portion of a burl top.
18. The method of any of the previous clauses, wherein the chemical cleaning agent comprises potassium hydroxide for tantalum contamination particles, a chrome etchant for chrome contamination particles, or a combination thereof.
19. The method of any of the previous clauses, wherein the cleaning tool is a glass puck.
20. The method of any of the previous clauses, wherein the relative movement comprises lateral movement, serpentine movement, circular movement, or a combination thereof.
21. The method of any of the previous clauses, wherein the object support is a clamp.
22. The method of any of the previous clauses, wherein the cleaning comprises flattening and/or removal of the contamination particles.
23. The method of any of the previous clauses, wherein applying the chemical cleaning agent, causing the relative movement, and applying the organic liquid are performed with the clamp coupled to a chuck of the lithography apparatus.
24. The method of any of the previous clauses, wherein applying the chemical cleaning agent, causing the relative movement, and applying the organic liquid are performed with the clamp disconnected from a chuck of the lithography apparatus.
25. The method of any of the previous clauses, wherein the object support and the lithography apparatus are associated with semiconductor manufacturing.
26. A system for cleaning an object support of a lithography apparatus, comprising: a chemical cleaning agent configured to be applied to a surface of the object support to release contamination particles from the surface; a cleaning tool configured to be caused to move relative to the surface to clean the contamination particles from the surface; and an organic liquid configured to be applied on the surface to remove the chemical cleaning agent from the surface.
27. The system of any of the previous clauses, further comprising a pre-cleaning imager configured to generate image data of the surface confirming presence of the contamination particles and/or one or more types of the contamination particles.
28. The system of any of the previous clauses, wherein the image data comprises one or more images from a microscope inspection of the surface.
29. The system of any of the previous clauses, further comprising a computer system configured to determine a pre-cleaning initial flatness of the surface to confirm presence of the contamination particles and a need for cleaning.
30. The system of any of the previous clauses, wherein the initial flatness is determined using high voltage phase measurement interferometry, and the computer system forms a portion of a high voltage phase measurement interferometer.
31. The system of any of the previous clauses, further comprising a microscope configured for determining a pre-cleaning contamination particle distribution map for the surface.
32. The system of any of the previous clauses, wherein the contamination particle distribution map is determined using a microscope inspection.
33. The system of any of the previous clauses, wherein the contamination particle distribution map is determined using white light interferometry and a white light interferometer.
34. The system of any of the previous clauses, further comprising a computer system configured for determining, based on image data of the surface, flatness of the surface, and/or contamination particle distribution on the surface, whether and/or where on the surface to apply the chemical cleaning agent, where to cause the relative movement between the cleaning tool and the surface, and/or where to apply the organic liquid.
35. The system of any of the previous clauses, further comprising an ion beam figuring system configured for performing a post-cleaning uniform ion beam figuring on the surface.
36. The system of any of the previous clauses, wherein the contamination particles are either already completely removed or reduced in size to a small enough size that the uniform ion beam figuring can then remove the contamination particles.
37. The system of any of the previous clauses, further comprising a computer system configured for determining a post-cleaning contamination particle distribution map for the surface, and comparing the post-cleaning contamination particle distribution map to a pre-cleaning contamination particle distribution map for the surface to confirm the method for cleaning successfully removed most or all of the contamination particles from the surface.
38. The system of any of the previous clauses, wherein the post-cleaning contamination particle distribution map is determined using white light interferometry.
39. The system of any of the previous clauses, further comprising a computer system configured for determining a post-cleaning flatness of the surface, and comparing the post-cleaning flatness to a pre-cleaning initial flatness of the surface to confirm the method for cleaning successfully removed most or all of the contamination particles from the surface.
40. The system of any of the previous clauses, wherein the post-cleaning flatness is determined using high voltage phase measurement interferometry.
41. The system of any of the previous clauses, wherein, responsive to the post-cleaning flatness breaching a flatness threshold, ion beam figuring is performed on the surface to bring the post-cleaning flatness within a flatness specification.
42. The system of any of the previous clauses, wherein the surface comprises a burl top or a portion of a burl top.
43. The system of any of the previous clauses, wherein the chemical cleaning agent comprises potassium hydroxide for tantalum contamination particles, a chrome etchant for chrome contamination particles, or a combination thereof.
44. The system of any of the previous clauses, wherein the cleaning tool is a glass puck.
45. The system of any of the previous clauses, wherein the relative movement comprises lateral movement, serpentine movement, circular movement, or a combination thereof.
46. The system of any of the previous clauses, wherein the object support is a clamp.
47. The system of any of the previous clauses, wherein the cleaning comprises flattening and/or removal of the contamination particles.
48. The system of any of the previous clauses, wherein applying the chemical cleaning agent, causing the relative movement, and applying the organic liquid are performed with the clamp coupled to a chuck of the lithography apparatus.
49. The system of any of the previous clauses, wherein applying the chemical cleaning agent, causing the relative movement, and applying the organic liquid are performed with the clamp disconnected from a chuck of the lithography apparatus.
50. The system of any of the previous clauses, wherein the object support and the lithography apparatus are associated with semiconductor manufacturing.
51. A system for cleaning a reticle clamp of a lithography apparatus, comprising a chemical cleaning agent configured to be applied to a surface of the reticle clamp to release contamination particles from the surface, a cleaning tool configured to move relative to the surface to clean the contamination particles from the surface, and an organic liquid configured to be applied on the surface to remove the chemical cleaning agent from the surface.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for wafer manufacturing on a substrate such as a silicon wafer, it shall be understood that the disclosed concepts may be used with any type of manufacturing system, e.g., those used for manufacturing on substrates other than silicon wafers. In addition, the combination and sub-combinations of disclosed elements may comprise separate embodiments. For example, the cleaning system and/or method, and the associated lithography apparatus may comprise separate embodiments, and/or these features may be used together in the same embodiment.

The descriptions above are intended to be illustrative, not limiting. Thus, it will be apparent to one skilled in the art that modifications may be made as described without departing from the scope of the claims set out below.

1. A method for cleaning an object support of a lithography apparatus, the method comprising:
applying a chemical cleaning agent to a surface of the object support to release contamination particles from the surface;
causing relative movement between a cleaning tool and the surface to clean the contamination particles from the surface; and
applying an organic liquid on the surface to remove the chemical cleaning agent from the surface.

2. The method of claim 1, wherein applying the chemical cleaning agent, causing relative movement, and applying the organic liquid are performed with a clamp coupled to a chuck of the lithography apparatus or with the clamp disconnected from a chuck of the lithography apparatus.

3. A system for cleaning an object support of a lithography apparatus, the system comprising:
a chemical cleaning agent configured to be applied to a surface of the object support to release contamination particles from the surface;
a cleaning tool configured to move relative to the surface to clean the contamination particles from the surface; and
an organic liquid configured to be applied on the surface to remove the chemical cleaning agent from the surface.

4. The system of claim 3, further comprising a pre-cleaning imager configured to generate image data of the surface confirming presence of the contamination particles and/or one or more types of the contamination particles, wherein the image data comprises one or more images from a microscope inspection of the surface.

5. The system of claim 3, further comprising a computer system configured to determine a precleaning initial flatness of the surface to confirm presence of the contamination particles and a need for cleaning, wherein the initial flatness is determined using high voltage phase measurement interferometry by a high voltage phase measurement interferometer.

6. The system of claim 3, further comprising a microscope configured to determine a precleaning contamination particle distribution map for the surface, wherein the contamination particle distribution map is determined using a microscope inspection.

7. The system of claim 6, wherein the contamination particle distribution map is further determined using white light interferometry and a white light interferometer.

8. The system of claim 3, further comprising a computer system configured to determine based on image data of the surface, on flatness of the surface, and/or on contamination particle distribution on the surface:
whether and/or where on the surface to apply the chemical cleaning agent;
where to cause relative movement between the cleaning tool and the surface; and/or where to apply the organic liquid.

9. The system of claim 3, further comprising an ion beam figuring system configured to perform a post-cleaning uniform ion beam figuring on the surface, wherein the contamination particles are either already completely removed or reduced in size to a small enough size that the uniform ion beam figuring can then remove the contamination particles.

10. The system of claim 3, further comprising a computer system configured to determine a post-cleaning contamination particle distribution map for the surface, and compare comparing the post-cleaning contamination particle distribution map to a pre-cleaning contamination particle distribution map for the surface to confirm cleaning successfully removed most or all of the contamination particles from the surface, wherein the post-cleaning contamination particle distribution map is determined using white light interferometry.

11. The system of claim 3, further comprising a computer system configured to determine a post-cleaning flatness of the surface, and compare the post-cleaning flatness to a pre-cleaning initial flatness of the surface to confirm cleaning successfully removed most or all of the contamination particles from the surface, wherein the post-cleaning flatness is determined using high voltage phase measurement interferometry.

12. The system of claim 11, configured to responsive to the post-cleaning flatness breaching a flatness threshold, perform ion beam figuring on the surface to bring the post-cleaning flatness within a flatness specification.

13. The system of claim 3, wherein:
the surface comprises a burl top or a portion of a burl top;
the chemical cleaning agent comprises potassium hydroxide for tantalum contamination particles, a chrome etchant for chrome contamination particles, or a combination thereof;
the cleaning tool is a glass puck;
the relative movement comprises lateral movement, serpentine movement, circular movement, or a combination selected therefrom;
the object support is a clamp;
the cleaning comprises flattening and/or removal of the contamination particles; and the object support and the lithography apparatus are associated with semiconductor manufacturing.

14. The system of claim 3, wherein the object support and the lithography apparatus are associated with semiconductor manufacturing.

15. A system for cleaning a reticle clamp of a lithography apparatus, the system comprising:
a chemical cleaning agent configured to be applied to a surface of the reticle clamp to release contamination particles from the surface;
a cleaning tool configured to move relative to the surface to clean the contamination particles from the surface; and
an organic liquid configured to be applied on the surface to remove the chemical cleaning agent from the surface.

16. The system of claim 15, further comprising a computer system configured to determine a precleaning initial flatness of the surface to confirm presence of the contamination particles and a need for cleaning, wherein the initial flatness is determined using high voltage phase measurement interferometry by a high voltage phase measurement interferometer.

17. The system of claim 15, further comprising a microscope configured to determine a precleaning contamination particle distribution map for the surface, wherein the contamination particle distribution map is determined using a microscope inspection.

18. The system of claim 17, wherein the contamination particle distribution map is further determined using white light interferometry and a white light interferometer.

19. The system of claim 15, further comprising a computer system configured to determine, based on image data of the surface, on flatness of the surface, and/or on contamination particle distribution on the surface:
whether and/or where on the surface to apply the chemical cleaning agent;
where to cause relative movement between the cleaning tool and the surface; and/or
where to apply the organic liquid.

20. The system of claim 15, further comprising a computer system configured to:
determine a post-cleaning contamination particle distribution map for the surface, and compare the post-cleaning contamination particle distribution map to a pre-cleaning contamination particle distribution map for the surface to confirm cleaning successfully removed most or all of the contamination particles from the surface, wherein the post-cleaning contamination particle distribution map is determined using white light interferometry; or
determine a post-cleaning flatness of the surface, and compare the post-cleaning flatness to a pre-cleaning initial flatness of the surface to confirm cleaning successfully removed most or all of the contamination particles from the surface, wherein the post-cleaning flatness is determined using high voltage phase measurement interferometry.
